(19) United States
(12) Patent Application Publication
(10) Pub. No.: US 2009/0218943 A1
(43) Pub. Date: Sep. 3, 2009

(54) DISPLAY DEVICE AND ELECTRONIC EQUIPMENT

(75) Inventors: Teiichiro Nishimura, Kanagawa (JP); Kaoru Abe, Kanagawa (JP); Reo Asaki, Tokyo (JP); Masahiro Mitani, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: SONY CORPORATION, Tokyo (JP)

(21) Appl. No.: 12/372,844

(22) Filed: Feb. 18, 2009

(30) Foreign Application Priority Data
Mar. 3, 2008 (JP) 2008-052136

(51) Int. Cl. G02B 5/00; H01J 1/62

(52) U.S. Cl. 313/512; 359/513

(57) ABSTRACT

A display device includes: a display area having a resonator structure for resonating produced light; a protective film formed to cover the display area; a resin layer formed on the protective film; and a sealing layer attached by the resin layer, wherein the protective film includes a single silicon nitride layer, and has a refractive index between 1.65 and 1.75 at a wavelength of nm.

### CROSS REFERENCES TO RELATED APPLICATIONS

The present invention contains subject matter related to Japanese Patent Application JP 2008-052136 filed in the Japan Patent Office on Mar. 3, 2008, the entire contents of which being incorporated herein by reference.

### BACKGROUND OF THE INVENTION

1. Field of the Invention

The present invention relates to a display device with a display area having a resonator structure adapted to resonate produced light, and more particularly to a top-emission display device with high light extraction efficiency using organic electroluminescence elements and electronic equipment using the same.

2. Description of the Related Art

Organic electric field light-emitting elements are drawing attention today. These elements have an organic layer between its anode and cathode. The organic layer includes an organic hole transporting layer and organic light-emitting layer stacked one upon the other. On the other hand, these elements have drawbacks including low stability over time as typified by reduced light emission luminance and unstable light emission as a result of moisture absorption. In a display device using organic electric field light-emitting elements, therefore, the same elements are covered with a protective film to prevent access of moisture thereto.

From this viewpoint, therefore, a silicon oxide nitride film or silicon nitride film is used, for example, as a protective film adapted to cover the organic electric field light-emitting elements. A silicon oxide nitride film is low in refractive index and high in transmittance, which are significantly advantageous device characteristics. However, this film is poor in moisture resistance. As a result, the film must be formed considerably thick. Forming a thick film, however, leads to increased internal stress, causing the film to peel off the cathode electrode or producing microcracks therein. This results in a contradiction, i.e., degradation in characteristics and moisture resistance of the organic electric field light-emitting elements.

For silicon nitride, on the other hand, a plasma CVD (Chemical Vapor Deposition) method has been proposed in which only silane and nitrogen gases are used as source gases without using ammonia gas. A protective film made of a silicon nitride film thus formed remains free from cracks and does not peel off, thus ensuring stable operation of the organic electric field light-emitting elements (refer, for example, to Japanese Patent Laid-Open No. 2000-223264).

For a film forming method using silane, nitrogen and hydrogen gases as source gases, on the other hand, a three-layer structure has been proposed to provide reduced residual stress in the protective film and thereby prevent the film from peeling. The three-layer structure, which includes a high-density silicon nitride film between low-density silicon nitride films, is made possible by changing the nitrogen gas concentration so as to control the film thicknesses (refer, for example, to Japanese Patent Laid-Open No. 2004-63304). However, these methods lead to a reduced transmittance of the protective film. This causes a significantly reduced transmittance particularly for blue light wavelength (about 450 nm), thus resulting in reduced color reproducibility. For this reason, another method has been proposed in which ammonia gas is used to form a film with improved transmittance and excellent coverage (refer, for example, to Japanese Patent Laid-Open No. 2007-184251, hereinafter referred to as Patent Document 3).

### SUMMARY OF THE INVENTION

However, the method disclosed in Patent Document 3 leads to a high refractive index (e.g., 1.85 to 1.91) although offering excellent moisture resistance of the protective film. As a result, reflection occurs at the interface with the overlying resin layer. This, together with film interference, leads to a deviation in chromaticity and luminance of the light extracted across the surface due to film thickness distribution of the protective film if the film thickness is reduced. This makes it impossible to secure a sufficient process margin. Therefore, the film thickness must be increased to produce multiple interference so as to eliminate the deviation in chromaticity due to film thickness distribution. On the other hand, increasing the film thickness entails increased tact time and cost. Further, increasing the film thickness leads to a lower transmittance of the protective film than reducing the film thickness. The transmittance for blue light wavelength (about 450 nm) in particular will drop significantly, thus resulting in reduced color reproducibility.

The present embodiment is a display device which includes a display area having a resonator structure adapted to resonate produced light, a protective film formed to cover the display area, a resin layer formed on the protective film, and a sealing layer attached by the resin layer. The protective film includes a single silicon nitride layer. The protective film has a refractive index between 1.65 and 1.75 at a wavelength of 450 nm. The present embodiment is also electronic equipment having the display device in its main body enclosure.

Particularly, the protective film used in the present embodiment is formed by chemical vapor deposition using silane, ammonia and nitrogen gases. The same film includes low-refractive-index silicon nitride films stacked one upon the other. The protective film is between 100 nm and 1 μm in thickness. As a result, there is almost no stress in the protective film.

Therefore, the refractive index of the protective film is brought closer to that of the resin layer, providing a longer interference wavelength even if the protective film is reduced in thickness. This eliminates the color shift of the light extracted across the surface due to film thickness distribution.

For example, if the refractive index of the silicon nitride film serving as a protective film is reduced to a level lower than normal (refractive index of 1.65 to 1.75 at a wavelength of 450 nm) by adjusting the plasma CVD parameters, the interference wavelength will be longer even for the thinner film. This eliminates the color shift of the light extracted across the surface due to film thickness distribution, thus providing a sufficient process margin. Further, the reduction of film thickness contributes to improved transmittance and reduced tact time and cost. Still further, the formation of a film having excellent coverage with reduced refractive index contributes to improved sealing reliability. Still further, the internal stress of the film is nearly zero thanks to the reduction of film thickness, providing improved device characteristics.

Here, reflectance R of the interface between the resin layer and protective film (silicon nitride film) is given by the following equation where n1 is the refractive index of the silicon nitride film, and n2 the refractive index of the resin layer:

R=(n1−n2)²/(n1+n2)²

Therefore, the smaller n1, the smaller the interfacial reflectance can be and the smaller the amplitude of the interference waveform.

The present invention provides the following advantageous effects. That is, the present invention provides a thinner protective film with a lower refractive index, thus ensuring a weaker interference with the resin layer for smaller chromaticity and luminance distributions across the surface. This ensures improved transmittance and reduced efficiency variation resulting from variation across the surface. Further, improved efficiency contributes to a longer life. Still further, thinner protective film contributes to a shorter process tact time.

### BRIEF DESCRIPTION OF THE DRAWINGS

FIG. 1 is a schematic sectional diagram for describing the structure of a display device according to a present embodiment;

FIG. 2 is a table showing the refractive indexes of three different protective films for a wavelength;

FIG. 3 is a diagram illustrating the characteristics of the three different protective films;

FIGS. 4A to 4C are diagrams illustrating the change in chromaticity of each of red, green and blue due to film thickness distribution;

FIG. 5 is a table showing the results of comparison of efficiency and variation between red, green and blue;

FIG. 6 is a diagram illustrating the change in luminance as a function of operating time in each condition;

FIG. 7 is a table showing the half-life in each condition;

FIG. 8 is a diagrammatic sketch illustrating an example of a flat display device in a modular form;

FIG. 9 is a perspective view illustrating a television set to which the present embodiment is applied;

FIGS. 10A and 10B are perspective views illustrating a digital camera to which the present embodiment is applied;

FIG. 11 is a perspective view illustrating a laptop personal computer to which the present embodiment is applied;

FIG. 12 is a perspective view illustrating a video camcorder to which the present embodiment is applied;

FIGS. 13A to 13G are views illustrating a personal digital assistant such as mobile phone to which the present embodiment is applied;

FIG. 14 is a block diagram illustrating the configuration of a display/imaging device;

FIG. 15 is a block diagram illustrating a configuration example of an I/O display panel; and

FIG. 16 is a circuit diagram for describing the connection relationship between each pixel and a sensor readout horizontal driver.

### DETAILED DESCRIPTION OF THE PREFERRED EMBODIMENT

The preferred embodiment of the present invention will be described below with reference to the accompanying drawings.

### <Structure of the Display Device>

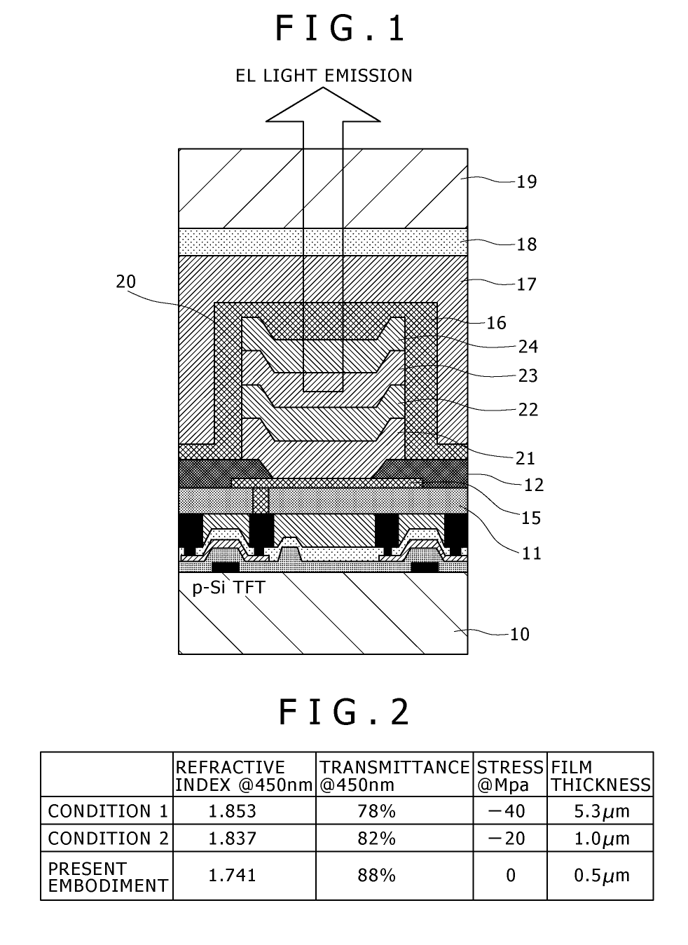

FIG. 1 is a schematic sectional diagram for describing the structure of a display device according to a present embodiment. It should be noted that a display device which includes a top-emission organic EL display is taken as an example in the present embodiment.

That is, this display device includes a drive substrate having a plurality of TFTs (Thin Film Transistors) arranged on an insulating substrate made, for example, of glass (glass substrate 10). The display device further includes a display area 20 formed on the drive substrate, a protective film 17 formed to cover the display area 20. The display device still further includes a resin layer 18 formed on the protective film 17 and a sealing layer 19 to be attached by the resin layer 18. The sealing layer 19 includes, for example, a glass substrate.

In a display device designed to display a color image, three different display areas, one adapted to emit red light, another adapted to emit green light, and still another adapted to emit blue light, are arranged in a matrix according to a predetermined sequence as the display area 20 formed on the drive substrate.

In the present embodiment, the display area 20 has a resonator structure adapted to resonate produced light. The display area 20 has an organic layer between a first electrode (e.g., anode 15) serving as a lower electrode and a second electrode (e.g., cathode 16) serving as an upper electrode. The organic layer includes a light-emitting layer 23. Light produced by the light-emitting layer 23 is resonated between the first and second electrodes and extracted from the side of the second electrode.

The organic layer included in the display area 20 may be configured in various manners. In the present embodiment, however, the organic layer includes, from the side of the anode 15, a hole injection layer 21, a hole transporting layer 22, the light-emitting layer 23 and an electron transporting layer 24. The hole injection layer 21 injects holes from the anode 15 into the organic layer 23. The hole transporting layer 22 efficiently transports the holes injected from the hole injection layer 21 to the light-emitting layer 23. The light-emitting layer 23 produces light by injection of a current. The electron transporting layer 24 injects electrons from the cathode 16 into the light-emitting layer 23.

The protective film 17 of the display area 20 is made of silicon nitride and is attached to the display area 20 to cover the same area 20. In the present embodiment, the protective film 17 includes a single silicon nitride layer which is formed to have a refractive index between 1.65 and 1.75 at a wavelength of 450 nm. This brings the refractive index of the protective film 17 close to that of the overlying resin layer 18 (1.5 to 1.6). This provides a longer interference wavelength even if the protective film is reduced in thickness, thus eliminating the color shift of the light extracted across the surface due to film thickness distribution. Particularly in the present embodiment, the difference in refractive index between the protective film 17 and resin layer 18 is 0.3 or less (preferably 0.2) at a wavelength of 450 nm. This provides improved suppression of color shift.

Here, the reflectance R of the interface between the protective film 17 and overlying resin layer 18 is given by the following equation where n1 is the refractive index of the silicon nitride film serving as the protective film 17, and n2 the refractive index of the resin layer:

R=(n1−n2)²/(n1+n2)²

Therefore, the smaller n1, the smaller the interfacial reflectance can be and the smaller the amplitude of the interference waveform.

The refractive index of the protective film 17 can be adjusted by adjusting the plasma CVD parameters used to form the protective film 17. The thickness of the same film 17 is between 100 nm and 1 μm. The internal stress of the film is nearly zero thanks to the reduction of film thickness. This suppresses the impact on the display area 20, thus providing improved light emission characteristics.

### <Manufacturing Processes of the Display Device>

A description will be given next of the manufacturing method of the display device according to the present embodiment in the order of processes. First, a TFT array is formed on a substrate made of an insulating material such as glass (glass substrate 10). The TFT array includes a plurality of TFTs arranged therein.

A first insulating film 11 is applied and formed on the glass substrate 10 on which the TFT array is formed. The first insulating film 11 is made of positive photosensitive polybenzoxazole and applied, for example, by spin coating. The same film 11 functions as a planarizing film adapted to planarize the irregularities produced on the surface of the glass substrate 10. Although polybenzoxazole is used in the present embodiment, other insulating material such as positive photosensitive polyimide may also be used.

Then, the first insulating film 11 is exposed to light and developed to form contact holes in the same film 11. The contact holes are used for connection with the TFTs. Next, the glass substrate 10 in this condition is baked in an inert gas atmosphere such as N₂ to harden polybenzoxazole and remove moisture and other substances from the first insulating film 11.

Next, a conductive material layer is formed on the first insulating film 11 in such a manner as to fill the contact holes. The conductive material layer includes an indium tin oxide (ITO) film, Ag alloy film and another ITO film stacked in this order from the side of the glass substrate surface. The thicknesses of the films making up the conductive material layer are, for example, about 30 nm, about 100 nm and about 10 nm respectively for the ITO film, Ag alloy film and ITO film from the side of the glass substrate 10. Here, the Ag alloy film serves as the reflecting layer of the lower electrode (anode 15) which is formed by patterning the conductive material layer in a subsequent process.

Next, the conductive material layer is patterned by etching using a resist pattern formed by normal lithography technique as a mask. This allows for the lower electrodes (anodes 15) to be arranged on the first insulating film 11 in the pixel area. Each of the lower electrodes (anodes 15) is associated with one of the pixels and connected to one of the TFTs via a contact hole. At the same time, a conductive film is formed on the first insulating film 11 in the surrounding area outside the pixel area. This conductive film is formed in the shape of a picture frame with a width of about 3 mm around the pixel area. The same film is connected to the drive circuits.

Here, the conductive film functions as an auxiliary wiring and will be connected to the upper electrode which will be formed in a subsequent process to reduce the wiring resistance. This provides improved luminance and excellent luminance distribution across the surface. Therefore, the conductive film should preferably be made of a material with excellent conductivity and be wide.

Next, a second insulating film 12 is applied and formed on the first insulating film 11 on which the lower electrode (anode 15) and conducive film are formed. The second insulating film 12 is made of positive photosensitive polybenzoxazole and applied, for example, by spin coating again.

Then, the second insulating film 12 is exposed to light, developed and hardened to form pixel openings used to form pixels, i.e., organic EL elements, in the pixel area, thus exposing the lower electrode (anode 15) surface and the conductive film surface in the surrounding area. Although polybenzoxazole is used in the present embodiment, other insulating material such as positive photosensitive polyimide may also be used.

Next, the glass substrate 10 in this condition is baked in an inert gas atmosphere such as N₂ to harden polybenzoxazole and remove moisture and other substances from the first and second insulating films 11 and 12.

Then, the glass substrate 10 is spin-washed to remove micro-foreign objects, after which the same substrate 10 is baked in a vacuum atmosphere. Then, the same substrate 10 is transported in a vacuum atmosphere to the pre-process chamber. In the pre-process chamber, the substrate 10 is pre-processed by O₂ plasma, after which the substrate is transported in a vacuum atmosphere to the next process for vacuum deposition of an organic layer. The above processes are preferred because they can prevent moisture and other particles in the atmosphere from being adsorbed onto the substrate surface.

Next, on the lower electrodes (anodes 15) in the pixel openings are formed organic layers of the organic EL elements of respective colors (red, green and blue organic EL elements), i.e., the red, green and blue organic layers.

In this case, the substrate is transported, for example, in a vacuum atmosphere to the chamber adapted to vacuum-deposit a blue organic layer. A vacuum deposition mask is aligned over the substrate. The hole injection layer 21, hole transporting layer 22, light-emitting layer 23 and electron transporting layer 24 are successively deposited in the pixel opening in such a manner as to cover the inner wall of the opening, thus forming a blue organic layer to the thickness of about 200 nm. The lower electrode is exposed on the bottom in the opening.

Next, in an atmosphere maintained under vacuum, the substrate is transported to the chamber adapted to vacuum-deposit a red organic layer. A vacuum deposition mask is aligned over the substrate. Then, a red organic layer is formed to the thickness of about 150 nm in the same manner as with the blue organic layer.

Then, in an atmosphere maintained under vacuum, the substrate is transported to the chamber adapted to vacuum-deposit a green organic layer. A vacuum deposition mask is aligned over the substrate. Then, a green organic layer is formed to the thickness of about 100 nm in the same manner as with the blue organic layer.

After the formation of the respective organic layers as described above, a vacuum deposition mask is aligned over the substrate in an atmosphere maintained under vacuum. Then, an electron injection layer (not shown) made of LiF is formed to the thickness of about 1 nm, for example, by vapor deposition on the organic layers, second insulating film 12 and conductive film.

Then, the upper electrode (cathode 16) made, for example, of translucent MgAg alloy is formed to the thickness of about 10 nm on the electron injection layer by vacuum vapor deposition using a vapor deposition mask. This connects the conductive film and upper electrode (cathode 16) together via the electron injection layer.

Then, SiNₓ (silicon nitride) is formed by CVD using silane, ammonia and nitrogen gases, which is the key feature of the present embodiment. Silicon nitride is formed in such a manner as to cover the organic layer and upper electrode (cathode 16) which serve as the display area 20 for each of the respective colors. Silicon nitride serves as the protective film 17.

After the formation of the protective film 17, the resin layer 18 is applied without exposure to atmosphere to form the sealing layer 19 for sealing purpose. The sealing layer 19 includes a glass substrate. An organic light-emitting element having an all solid-sealing structure is manufactured by the method described above.

### <Comparison of Characteristics of the Protective Films>

Here, the protective film disclosed in Japanese Patent Laid-Open No. 2007-184251 was formed as a comparative sample to describe the protective film according to the present embodiment. The film is 5.3 μm in thickness (condition 1). Further, a single-layer of the protective film disclosed in Japanese Patent Laid-Open No. 2007-184251 was formed as condition 2 to the thickness of 1 μm (condition 2). This condition is excellent in terms of life characteristics.

The protective film according to the present embodiment was formed by CVD using ammonia gas. This film having a refractive index n of 1.74 (450 nm wavelength) and a transmittance of 86% (450 nm wavelength) was obtained by a one-to-two or higher flow rate ratio between silane and ammonia gases or by increasing the pressure while maintaining the flow rates unchanged. The film was 0.5 μm in thickness. The above three different films are compared. It should be noted that FIG. 2 shows the characteristics of these protective films.

### COMPARISON EXAMPLE 1

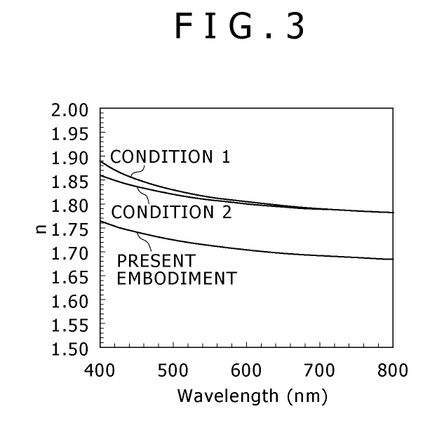

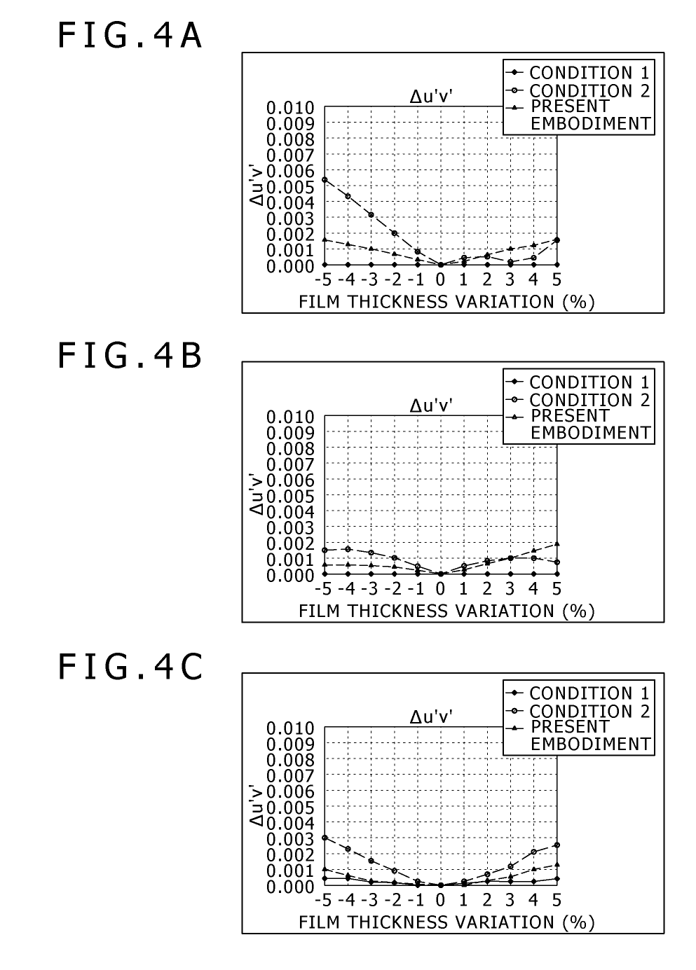

Comparison example 1 shows the results of comparison in terms of color shift due to film thickness distribution. First, FIG. 3 shows the measured results of the refractive indices of the above three films for wavelengths. FIGS. 4A to 4C illustrate, based on the results, the change of chromaticity due to film thickness distribution for each of red, green and blue. FIG. 4A illustrates the change of chromaticity for red, FIG. 4B that for green, and FIG. 4C that for blue. In each of these figures, the horizontal axis represents the film thickness variation, and the vertical axis the deviation in chromaticity u′v′.

It is clear from these figures that although the impact of interference is not visible in condition 1 due to averaging, the impact manifests itself in the form of characteristic change in condition 2. The comparison between condition 2 and the present embodiment makes it obvious that the protective film of the present embodiment is less likely to be affected by interference thanks to its lower refractive index.

### COMPARISON EXAMPLE 2

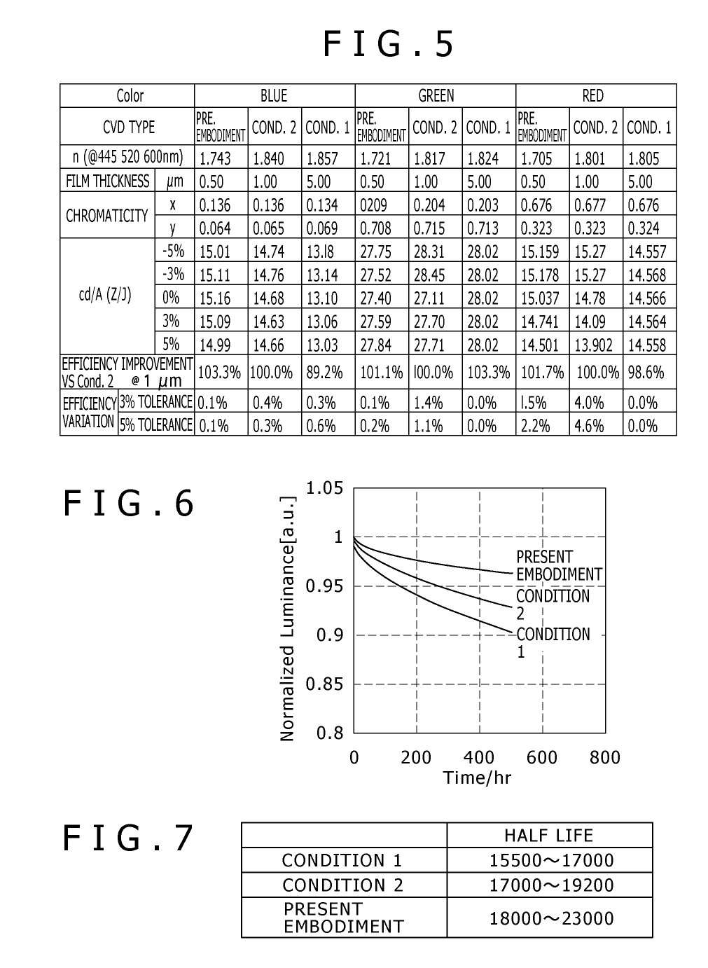

Comparison example 2 shows the results of comparison in terms of efficiency improvement and variation (precision) due to refractive index. FIG. 5 shows the results of comparison in terms of efficiency and variation for each color. FIG. 5 shows, for each of red, green and blue, the refractive index, film thickness, chromaticity (x and y coordinates) at that time, efficiency value due to film thickness distribution of the protective film, difference in efficiency as compared to condition 2, and efficiency variation (efficiency distribution due to film thickness distribution) of the protective films of the present embodiment, condition 1 and condition 2.

It is clear from the comparison between conditions 1 and 2 that condition 2 offers improved efficiency although there is not much difference in refractive index between the two. However, condition 2 has a larger variation in efficiency due to film thickness variation because of its smaller film thickness. On the other hand, the present embodiment tends to ensure minimal variation while at the same time providing improved efficiency by reducing the refractive index.

### COMPARISON EXAMPLE 3

Comparison example 3 shows the results of comparison in terms of life improvement. FIG. 6 illustrates the change in luminance as a function of operating time in each condition. As a result of the investigation of life characteristics by luminance matching, the present embodiment offers higher efficiency at the same luminance than conditions 1 and 2 thanks to its smaller film thickness. Therefore, it is clear that the life of blue, which is the most concerning of all colors, has improved. Further, FIG. 7 shows the calculated life of each film by finding the acceleration constant. The half life of the film of each condition is shown in FIG. 7. It is clear from this figure that the protective film of the present embodiment provides the longest life.

A description will be given next of application examples of the display device according to the present embodiment.

### <Electronic Equipment>

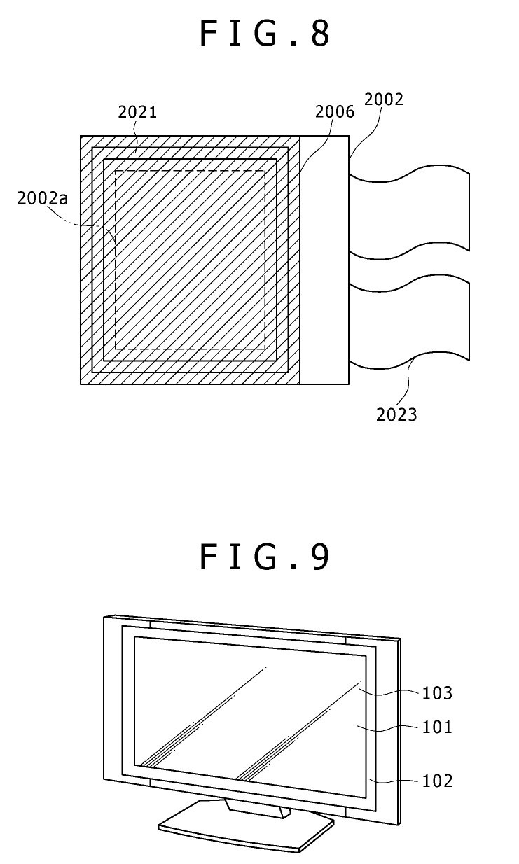

The display device according to the present embodiment includes a flat display device in a modular form as illustrated in FIG. 8. For example, a pixel array section 2002a is provided on an insulating substrate 2002. The pixel array section 2002a has pixels integrated and formed in a matrix. Each of the pixels includes a light-emitting area, thin film transistor, light receiving element and other components. An adhesive 2021 is applied around the pixel array section (pixel matrix section) 2002a, after which an opposed substrate 2006 made of glass or other material is attached for use as a display module. This transparent opposed substrate 2006 may have a color filter, protective film, light-shielding film and so on as necessary. An FPC (flexible printed circuit) 2023, adapted to allow exchange of signals or other information between external equipment and the pixel array section 2002a, may be provided as a connector on the display module.

The aforementioned display device according to the present embodiment is applicable as a display of a wide range of electronic equipment including a digital camera, laptop personal computer, personal digital assistant such as mobile phone and video camcorder illustrated in FIGS. 9 to 13. These pieces of equipment are designed to display an image or video of a video signal fed to or generated inside the electronic equipment. Examples of electronic equipment to which the present embodiment is applied will be described below.

FIG. 9 is a perspective view illustrating a television set to which the present embodiment is applied. The television set according to the present application example includes a video display screen section 101 made up, for example, of a front panel 102, filter glass 103 and other parts. The television set is manufactured by using the display device according to the present embodiment as the video display screen section 101.

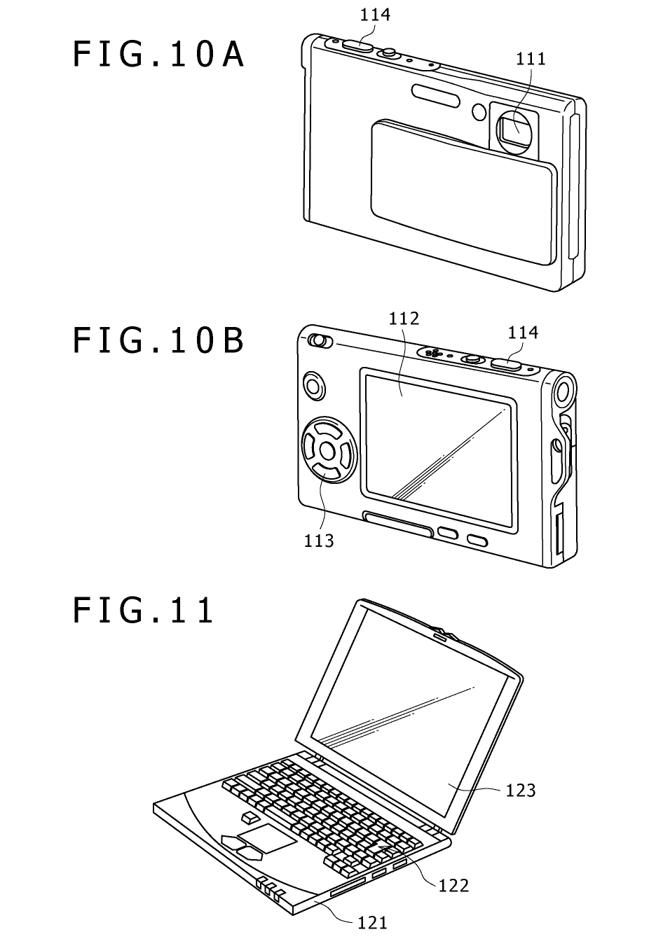

FIGS. 10A and 10B are views illustrating a digital camera to which the present embodiment is applied. FIG. 10A is a perspective view of the digital camera as seen from the front, and FIG. 10B is a perspective view thereof as seen from the rear. The digital camera according to the present application example includes a flash-emitting section 111, display section 112, menu switch 113, shutter button 114 and other parts. The digital camera is manufactured by using the display device according to the present embodiment as the display section 112.

FIG. 11 is a perspective view illustrating a laptop personal computer to which the present embodiment is applied. The laptop personal computer according to the present application example includes, in a main body 121, a keyboard 122 adapted to be manipulated for entry of text or other information, a display section 123 adapted to display an image, and other parts. The laptop personal computer is manufactured by using the display device according to the present embodiment as the display section 123.

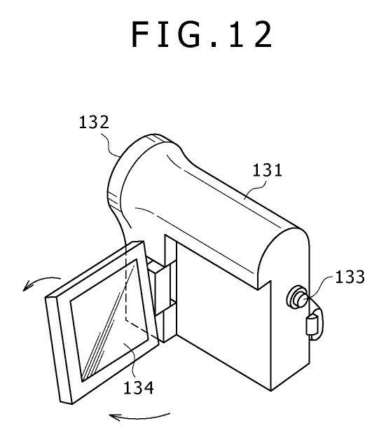

FIG. 12 is a perspective view illustrating a video camcorder to which the present embodiment is applied. The video camcorder according to the present application example includes a main body section 131, lens 132 provided on the front-facing side surface to capture the image of the subject, imaging start/stop switch 133, display section 134 and other parts. The video camcorder is manufactured by using the display device according to the present embodiment as the display section 134.

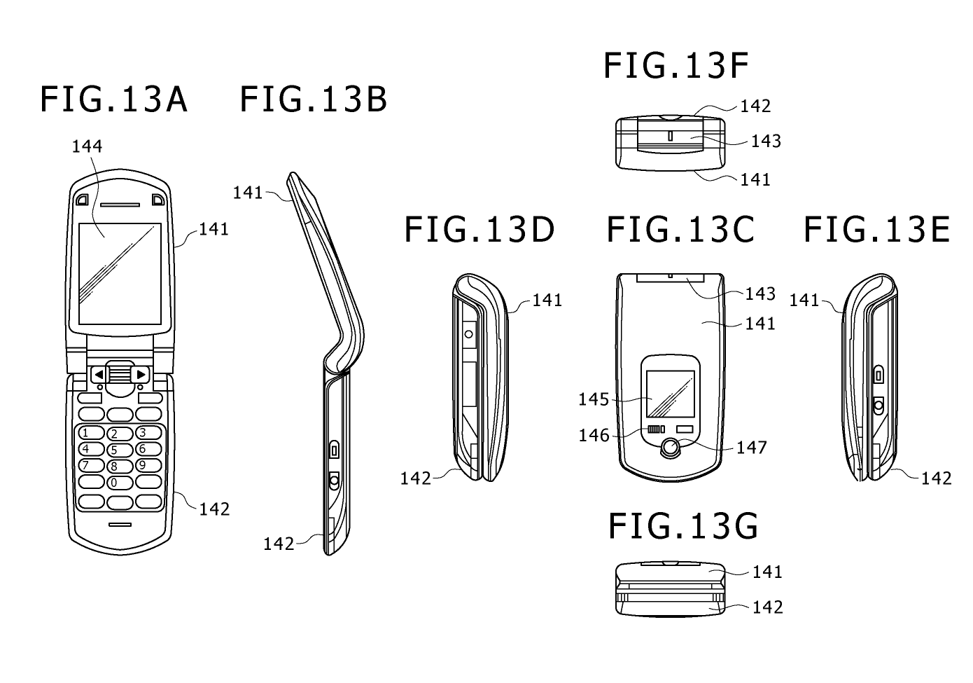

FIGS. 13A to 13G are perspective views illustrating a personal digital assistant such as mobile phone to which the present embodiment is applied. FIG. 13A is a front view of the mobile phone in an open position. FIG. 13B is a side view thereof. FIG. 13C is a front view of the mobile phone in a closed position. FIG. 13D is a left side view. FIG. 13E is a right side view. FIG. 13F is a top view. FIG. 13G is a bottom view. The mobile phone according to the present application example includes an upper enclosure 141, lower enclosure 142, connecting section (hinge section in this example) 143, display 144, subdisplay 145, picture light 146, camera 147 and other parts. The mobile phone is manufactured by using the display device according to the present embodiment as the display 144 and subdisplay 145.

### <Display/Imaging Device>

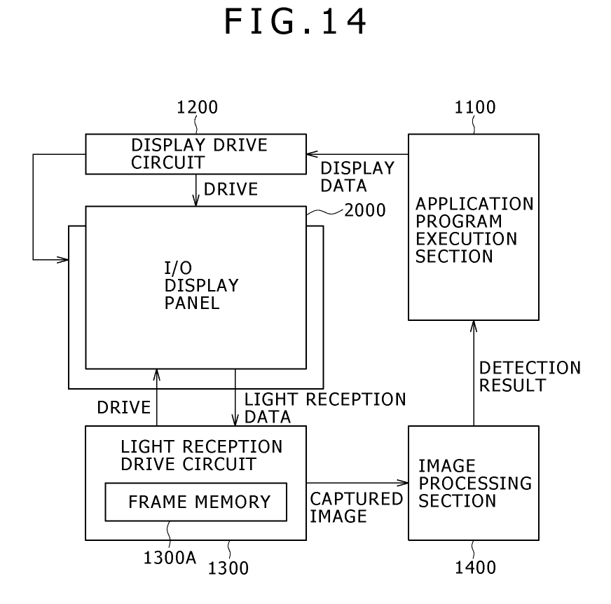

The display device according to the present embodiment is applicable to a display/imaging device described below. This display/imaging device is applicable to the various types of electronic equipment described earlier. FIG. 14 illustrates the overall configuration of the display/imaging device. This display/imaging device includes an I/O display panel 2000, backlight 1500, display drive circuit 1200, light reception drive circuit 1300, image processing section 1400 and application program execution section 1100.

The I/O display panel 2000 includes a plurality of pixels arranged in a matrix form over the entire surface. Each of the pixels includes an organic electric field light-emitting element. The same panel 2000 is capable of displaying an image such as predetermined graphics and text based on display data as it is driven sequentially line by line (display capability). At the same time, the same panel 2000 is capable of imaging an object in contact therewith or in proximity thereto (imaging capability), as described later. On the other hand, the backlight 1500 is a light source of the display panel I/O display panel 2000 and includes, for example, a plurality of light-emitting diodes arranged across its surface. The backlight 1500 is designed to turn the light-emitting diodes on and off quickly at predetermined timings in synchronism with the operation timings of the I/O display panel 2000 as described later.

The display drive circuit 1200 drives the I/O display panel 2000 (sequentially drives the I/O display panel 2000 line by line) to display an image on the same panel 2000 based on the display data (perform a display operation).

The light reception drive circuit 1300 drives the I/O display panel 2000 (sequentially drives the I/O display panel 2000 line by line) to obtain light reception data of the same panel 2000 (to image the object). It should be noted that the light reception data of each pixel is stored in a frame memory 1300A on a frame-by-frame basis and output to the image processing section 1400 as a captured image.

The image processing section 1400 performs predetermined image processing (arithmetic operation) based on the captured image from the light reception drive circuit 1300 to detect and obtain information about the object in contact with or in proximity to the I/O display panel 2000 (e.g., position coordinate data, object shape and size). It should be noted that this detection process will be described in detail later.

The application program execution section 1100 performs processing according to predetermined application software based on the detection result of the image processing section 1400. For example, among such processing is displaying the display data on the I/O display panel 2000 together with the position coordinates of the detected object. It should be noted that the display data generated by the application program execution section 1100 is supplied to the display drive circuit 1200.

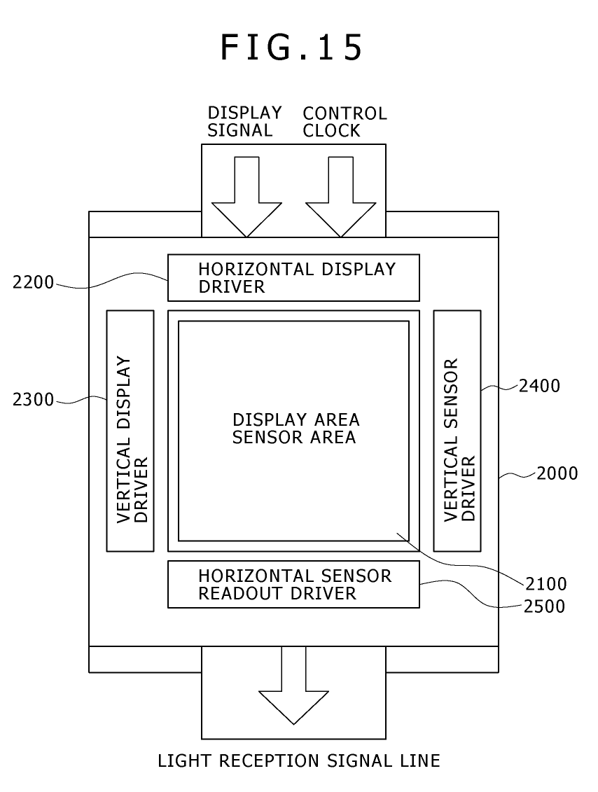

A description will be given next of a detailed example of the I/O display panel 2000 with reference to FIG. 15. The I/O display panel 2000 includes a display area (sensor area) 2100, horizontal display driver 2200, vertical display driver 2300, horizontal sensor readout driver 2500 and vertical sensor driver 2400.

The display area (sensor area) 2100 modulates light from the organic electric field light-emitting elements to emit display light and image an object in contact therewith or in proximity thereto. In this area, the organic electric field light-emitting elements serving as the light-emitting elements (display elements) and light receiving elements (imaging elements), which will be described later, are both arranged in a matrix form.

The horizontal display driver 2200 drives, together with the vertical display driver 2300, the organic electric field light-emitting elements of the respective pixels in the display area 2100 based on the display driving display signal and control clock supplied from the display drive circuit 1200.

The horizontal sensor readout driver 2500 sequentially drives, together with the vertical sensor driver 2400, the light receiving elements of the respective pixels in the sensor area 2100 line by line to obtain a light reception signal.

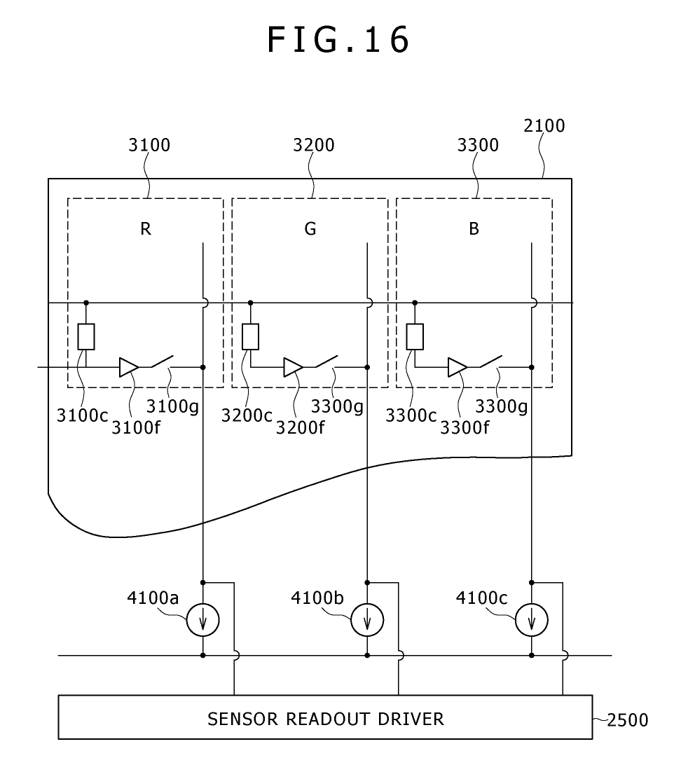

A description will be given next of the connection relationship between each of the pixels in the display area 2100 and the horizontal sensor readout driver 2500 with reference to FIG. 16. In the display area 2100, red (R) pixel 3100, green (G) pixel 3200 and blue (B) pixel 3300 are arranged side by side.

The charge stored in a capacitor connected to each of light receiving elements 3100c, 3200c and 3300c of the pixels of respective colors is amplified respectively by buffer amplifiers 3100f, 3200f and 3300f and supplied to the horizontal sensor readout driver 2500 via a signal output electrode when readout switches 3100g, 3200g and 3300g turn on. It should be noted that a constant current source 4100a, 4100b or 4100c is connected to each of the signal output electrodes so that the horizontal sensor readout driver 2500 can detect the signal commensurate with the amount of received light with high sensitivity.

It should be understood by those skilled in the art that various modifications, combinations, sub-combinations and alterations may occur depending on design requirements and other factors insofar as they are within the scope of the appended claims or the equivalents thereof.

What is claimed is:

1. A display device comprising:
a display area having a resonator structure for resonating produced light;
a protective film formed to cover the display area;
a resin layer formed on the protective film; and
a sealing layer attached by the resin layer, wherein
the protective film includes a single silicon nitride layer, and has a refractive index between 1.65 and 1.75 at a wavelength of 450 nm.

2. The display device of claim 1, wherein
the internal stress of the protective film is nearly zero.

3. The display device of claim 1, wherein
the protective film is between 100 nm and 1 μm in thickness.

4. The display device of claim 1, wherein
the display area is covered by the protective film so as not to be exposed to the atmosphere.

5. The display device of claim 1, wherein
the display area has an organic layer including a light-emitting layer between first and second electrodes, and has organic light-emitting elements adapted to extract light produced by the light-emitting layer from the side of the second electrode.

6. The display device of claim 1, wherein
the difference in refractive index between the protective film and resin layer is 0.3 or less at a wavelength of 450 nm.

7. Electronic equipment having a display device in its main body enclosure, the display device comprising:
a display area having a resonator structure for resonating produced light;
a protective film formed to cover the display area;
a resin layer formed on the protective film; and
a sealing layer attached by the resin layer, wherein
the protective film includes a single silicon nitride layer, and has a refractive index between 1.65 and 1.75 at a wavelength of 450 nm.
